(19) United States
(12) Patent Application Publication
(10) Pub. No.: US 2026/0363075 A1
(43) Pub. Date: Nov. 12, 2026

(54) COOLING DEVICE

(71) Applicant: MITSUBISHI HEAVY INDUSTRIES, LTD., Tokyo (JP)

(72) Inventor: Takashi Masuzawa, Tokyo (JP)

(73) Assignee: MITSUBISHI HEAVY INDUSTRIES, LTD., Tokyo (JP)

(21) Appl. No.: 19/135,210

(22) PCT Filed: Sep. 12, 2023
(86) PCT No.: PCT/JP2023/033142

§ 371 Date: Jun. 3, 2025

(30) Foreign Application Priority Data
Dec. 13, 2022 (JP) 2022-198364

(51) Int. Cl. H10W 40/47; H10W 90/10

(52) U.S. Cl. CPC H10W 40/47; H10W 90/10

(57) ABSTRACT

A cooling device for cooling a plurality of power modules each including a substrate body and a semiconductor element disposed on a surface of the substrate body, and arrayed in a first direction, includes: a cooling member including a heat transfer surface and provided in contact with a back surface of each of the substrate bodies; and a flow path forming member including a top surface portion in which an opening portion surrounding the heat transfer surface is formed and a bottom surface portion facing the top surface portion at an interval, and forming a flow path through which a refrigerant flows in the first direction between the bottom surface portion and the top surface portion. In the flow path, a flow path cross sectional area decreases from an upstream side toward a downstream side in a flow direction of the refrigerant.

### TECHNICAL FIELD

The present disclosure relates to a cooling device. Priority is claimed on Japanese Patent Application No. 2022-198364, filed on Dec. 13, 2022, the content of which is incorporated herein by reference.

### BACKGROUND ART

For example, in a power module used in a power supply circuit, a large current flows through a semiconductor element in the power module. Therefore, a large amount of heat is generated due to a conduction loss and a switching loss which occur in the semiconductor element. When this heat is progressively generated, there is a possibility that thermal runaway of an element or a damage to the element occurs. Therefore, various cooling devices for cooling the power module have been proposed so far. Specific examples of the cooling device include those described in Patent Document 1.

In the device according to Patent Document 1, a cooling member including a heat radiation fin is attached to a lower surface side of a plurality of circuit boards. Furthermore, a flow path through which a refrigerant flows is formed on a lower surface side of the circuit board to be in contact with the heat radiation fin. A flow path cross sectional area of the flow path gradually decreases from an upstream side toward a downstream side in a flow direction of the refrigerant.

### CITATION LIST

### Patent Document

Patent Document 1: Japanese Unexamined Patent Application, First Publication No. 2010-153785

### SUMMARY OF INVENTION

### Technical Problem

Here, since the semiconductor element used in the above-described power supply circuit or the like may reach a considerably high temperature, it is conceivable that a temperature of a heat transfer surface exceeds a boiling point and a cooling medium boils. In this case, in the device disclosed in Patent Document 1 above, air bubbles are generated in a gap between the heat radiation fins. When the air bubbles continue to stay inside the gap, the air bubbles are interposed between the heat radiation fin and the refrigerant. Consequently, the power module is brought into an adiabatic state which is a so-called dry-out state. That is, a cooling effect obtained by the refrigerant cannot be maintained. As a result, cooling of the semiconductor element becomes unstable, and as a result, an element temperature excessively increases, thereby causing a possibility of thermal destruction.

The present disclosure has been made to solve the above-described problems, and an object of the present disclosure is to provide a cooling device which can stably cool a semiconductor element.

### Solution to Problem

According to the present disclosure, in order to solve the above-described problem, there is provided a cooling device for cooling a plurality of power modules each including a substrate body and a semiconductor element disposed on a surface of the substrate body, and arrayed in a first direction. The cooling device includes a cooling member including a heat transfer surface and provided in contact with a back surface of each of the substrate bodies, and a flow path forming member including a top surface portion in which an opening portion surrounding the heat transfer surface is formed and a bottom surface portion facing the top surface portion at an interval, and forming a flow path through which a refrigerant flows in the first direction between the bottom surface portion and the top surface portion. In the flow path, a flow path cross sectional area decreases from an upstream side toward a downstream side in a flow direction of the refrigerant. Each flow disturbance portion configured to disturb a flow of the refrigerant is provided in a region between the power modules in the flow path forming member.

According to the present disclosure, there is provided a cooling device for cooling a plurality of power modules each including a substrate body and a semiconductor element disposed on a surface of the substrate body, and arrayed in a first direction. The cooling device includes a cooling member including a heat transfer surface and provided in contact with a back surface of each of the substrate bodies, and a flow path forming member including a top surface portion in which an opening portion surrounding the heat transfer surface is formed and a bottom surface portion facing the top surface portion at an interval, and forming a flow path through which a refrigerant flows in the first direction between the bottom surface portion and the top surface portion. In the flow path, a flow path cross sectional area decreases from an upstream side toward a downstream side in a flow direction of the refrigerant. The cooling member includes a cooling member body configured to come into contact with the substrate body, and a plurality of protrusions protruding from the cooling member body toward the bottom surface portion. The protrusion length of the protrusion is equal to or smaller than a thickness of the top surface portion.

### Advantageous Effects of Invention

According to the present disclosure, it is possible to provide a cooling device which can stably cool a semiconductor element.

### BRIEF DESCRIPTION OF DRAWINGS

FIG. 1 A cross sectional view showing the configuration of a cooling device according to a first embodiment of the present disclosure.

FIG. 2 A cross sectional view showing a first modification example of the cooling device according to the first embodiment of the present disclosure.

FIG. 3 A cross sectional view showing a second modification example of the cooling device according to the first embodiment of the present disclosure.

FIG. 4 A cross sectional view showing the configuration of a cooling device according to a second embodiment of the present disclosure.

FIG. 5 A cross sectional view showing the configuration of a cooling device according to a third embodiment of the present disclosure.

FIG. 6 A cross sectional view showing a modification example of the cooling device according to the third embodiment of the present disclosure.

### DESCRIPTION OF EMBODIMENTS

### First Embodiment

### (Configuration of Circuit System)

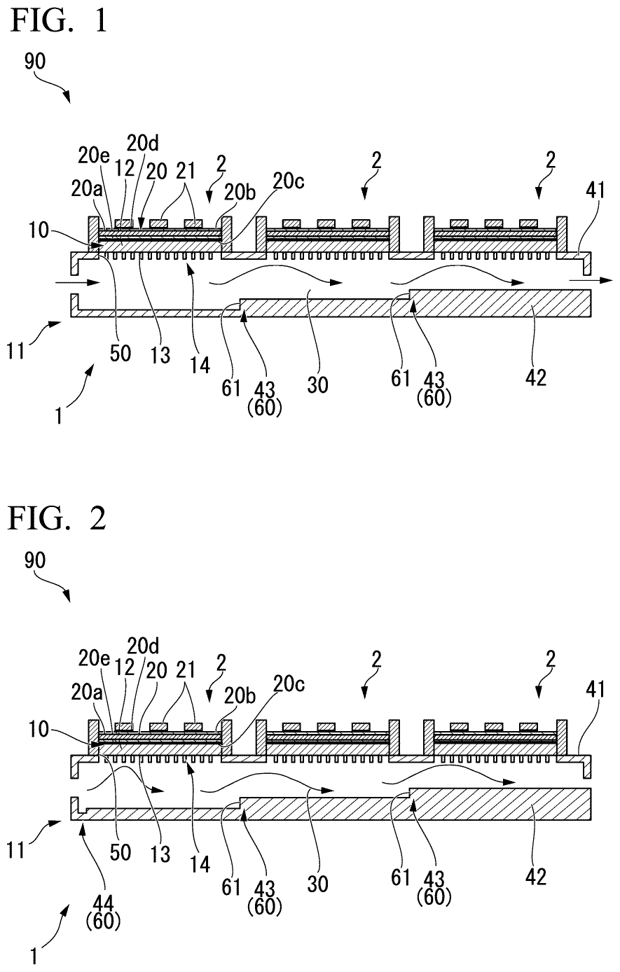

Hereinafter, a cooling device 1 according to a first embodiment of the present disclosure will be described with reference to FIG. 1. The cooling device 1 is a device for cooling a semiconductor element 21 used in a circuit system 90 that handles a large current, such as a power supply circuit.

As shown in FIG. 1, the circuit system 90 includes a plurality of power modules 2 and the cooling device 1.

The power module 2 includes a substrate body 20 and the semiconductor element 21. The substrate body 20 includes an insulator 20a and a pattern 20b (bonding material). For example, the insulator 20a has a plate shape formed of a material such as alumina, silicon nitride, or aluminum nitride. Circuit patterns 20b and 20c formed of a copper foil are provided on both surfaces of the insulator 20a in a thickness direction. The semiconductor element 21 is electrically connected to the pattern 20b by a conductive bonding member 20d such as solder. For example, the semiconductor element 21 is a MOSFET or a power transistor, and a current flows in the semiconductor element 21 such that heat is generated due to internal resistance. In addition, the pattern 20b and the cooling member 10 (to be described later) are also bonded by the bonding member 20e in the same manner.

A plurality of (for example, three) semiconductor elements 21 are attached to a surface of the substrate body 20. The number of the semiconductor elements 21 is not limited to three, and may be two or less, or may be four or more. The cooling device 1 is provided on a back surface side of the substrate body 20 (that is, a side opposite to a surface on which the semiconductor element 21 is provided).

### (Configuration of Cooling Device)

The cooling device 1 includes a cooling member 10 and a flow path forming member 11. The cooling member 10 includes a cooling member body 12 and a plurality of protrusions 13. The cooling member body 12 has a plate shape that comes into contact with a back surface of the substrate body 20. The protrusion 13 protrudes from a back surface of the cooling member body 12. The plurality of protrusions 13 are arrayed at an interval from each other. Specific examples of a shape of the protrusion 13 include a fin and a pin. A surface on a side including the protrusion 13 in the cooling member 10 is set as a heat transfer surface 14. The heat transfer surface 14 described here is a surface having unevenness including an outer surface such as a side surface or a tip surface of the protrusion 13. The cooling member 10 is integrally formed of metal having a high heat transfer rate, such as aluminum or copper. The cooling member 10 can also be configured such that the cooling member body 12 and the protrusion 13 are joined together after being formed as separate members.

The flow path forming member 11 forms a flow path 30 for causing a refrigerant to flow on the heat transfer surface 14 of the cooling member 10. The flow path forming member 11 includes a top surface portion 41, a bottom surface portion 42, and a flow disturbance portion 43. The top surface portion 41 has a plate shape spreading along an extending surface of the power module 2. A plurality of the power modules 2 are arrayed at an interval from each other on the top surface portion 41. Hereinafter, a direction in which the power modules 2 are arrayed may be referred to as a “first direction”. A plurality of opening portions 50 surrounding the heat transfer surface 14 are formed in the top surface portion 41. That is, each heat transfer surface 14 is exposed in the flow path 30 through the opening portion 50. The protrusion length of the protrusion 13 is equal to or smaller than the thickness dimension of the top surface portion 41. That is, when viewed in the first direction, the protrusion 13 is accommodated in the opening portion 50, and does not protrude in the flow path 30.

The bottom surface portion 42 faces the top surface portion 41 at an interval therebetween. A space formed between the top surface portion 41 and the bottom surface portion 42 forms the flow path 30 through which the refrigerant flows. In the flow path 30, the refrigerant flows from one side toward the other side in the first direction. As the refrigerant, for example, a liquid such as ethylene glycol or pure water is suitably used. In the following description, a side to which the refrigerant flows in the first direction may be referred to as an “upstream side”, and a side opposite thereto may be referred to as a “downstream side”.

A plurality of flow disturbance portions 43 are formed in the bottom surface portion 42. In the present embodiment, a plurality of step difference portions 60 are formed as the flow disturbance portions 43. Each of the step difference portions 60 includes a step difference surface 61 which is a surface facing the upstream side. In this manner, a surface of the bottom surface portion 42 is gradually closer to a side of the top surface portion 41 from the upstream side toward the downstream side. In the first direction, the step difference portion 60 is located between a pair of circuit boards 2 adjacent to each other. That is, a surface facing the heat transfer surface 14 in the bottom surface portion 42 spreads in a plane parallel to the substrate body 20. Since the surface has this shape, a flow path cross sectional area of the flow path 30 gradually decreases from the upstream side toward the downstream side.

### (Operational Effect)

In operating the cooling device 1, first, the refrigerant is caused to flow in the flow path 30. When a current flows to the semiconductor element 21 in this state, the semiconductor element 21 generates heat due to internal resistance. When heat generation increases, there is a possibility of causing thermal runaway of the semiconductor element 21 or a damage to the semiconductor element 21. Therefore, the cooling device 1 cools the semiconductor element 21. Specifically, the refrigerant continuously flowing in the flow path 30 comes into contact with the heat transfer surface 14. In this manner, the heat of the semiconductor element 21 is removed via the substrate body 20. That is, the semiconductor element 21 itself is cooled by the refrigerant.

Here, when a plurality of the power modules 2 are arrayed in the first direction as described above and the refrigerant flows in the first direction, a temperature of the refrigerant to be supplied increases as the refrigerant is closer toward the power module 2 on the downstream side. As a result, there is a possibility that a cooling effect on the semiconductor element 21 on the downstream side is limited. In order to reduce this possibility, the cooling device 1 according to the present embodiment adopts each of the above-described configurations.

According to the above-described configuration, the flow path cross sectional area of the flow path 30 decreases toward the downstream side. In this manner, a flow velocity of the refrigerant increases toward the downstream side. As the flow velocity increases, a thickness of a boundary layer formed in the vicinity of a surface of the top surface portion 41 or the bottom surface portion 42 decreases. Therefore, a heat transfer rate of the refrigerant apparently increases. In this manner, the heat transfer rate of the refrigerant increases toward the power module 2 on the downstream side, and the cooling effect can be improved. As a result, the power module 2 can be more stably operated.

Furthermore, a flow direction of the refrigerant is changed since the refrigerant flowing in the flow path 30 collides with the step difference surface 61 serving as the flow disturbance portion 43. Specifically, the refrigerant flows in a direction from a side of the bottom surface portion 42 toward a side of the top surface portion 41 by colliding with the step difference surface 61. In addition, a vortex is likely to be formed on the downstream side of the step difference portion 60. In this manner, the refrigerant in which a temperature gradient is formed when supplied to cool the power module 2 on the upstream side is stirred on the downstream side of the step difference portion 60. As a result, the refrigerant flows toward the power module 2 on the downstream side in a state where the temperature gradient is eliminated. Therefore, since a temperature increase on a side of the heat transfer surface 14 of the refrigerant flowing to the downstream side is suppressed, the cooling effect on the power module 2 on the downstream side can be further improved.

In addition, according to the above-described configuration, the flow path cross sectional area of the flow path 30 can be reduced toward the downstream side only by forming the step difference portion 60. In this manner, the flow velocity of the refrigerant increases toward the downstream side. In addition, the refrigerant collides with the step difference surface 61 of the step difference portion 60. Accordingly, a flow disturbance including a vortex is generated on the downstream side of the step difference portion 60. As a result, as described above, the refrigerant is stirred, and the temperature gradient of the refrigerant is leveled. Accordingly, the cooling effect on the power module 2 on the downstream side can be easily improved.

In addition, according to the above-described configuration, the protrusion length of the protrusion 13 of the cooling member 10 is equal to or smaller than the thickness of the top surface portion 41. In this manner, even when air bubbles are generated due to boiling of the refrigerant in a gap between the protrusions 13, a flow of the refrigerant is likely to reach the inside of the gap after climbing over the protrusions 13. Therefore, the air bubbles present inside the gap can be easily flowed away by the flow of the refrigerant. As a result, it is possible to further reduce a possibility that dry-out occurs due to the air bubbles interposed between the heat transfer surface 14 and the refrigerant. In this manner, the cooling effect on the semiconductor element 21 can be further improved.

Hitherto, the first embodiment of the present disclosure has been described. Various changes or modifications can be made to the above-described configuration without departing from the concept of the present disclosure.

For example, as shown in FIG. 2 as a first modification example, another flow disturbance portion 43 (upstream-side flow disturbance portion 44) can be provided on the further upstream side of the power module 2 on an uppermost stream side in the bottom surface portion 42. In the example of FIG. 2, specifically, another step difference portion 60 is further formed as the upstream-side flow disturbance portion 44. According to this configuration, when the air bubbles are generated due to the boiling of the refrigerant on the surface (heat transfer surface 14) of the cooling member 10 corresponding to the power module 2 on the uppermost stream side, the refrigerant passing through the upstream-side flow disturbance portion 44 flows toward the heat transfer surface 14. In this manner, the refrigerant is likely to flow between the protrusions 13, the air bubbles can be flowed away by the flow of the refrigerant. As a result, the cooling effect can be continuously maintained by avoiding occurrence of the dry-out on the heat transfer surface 14.

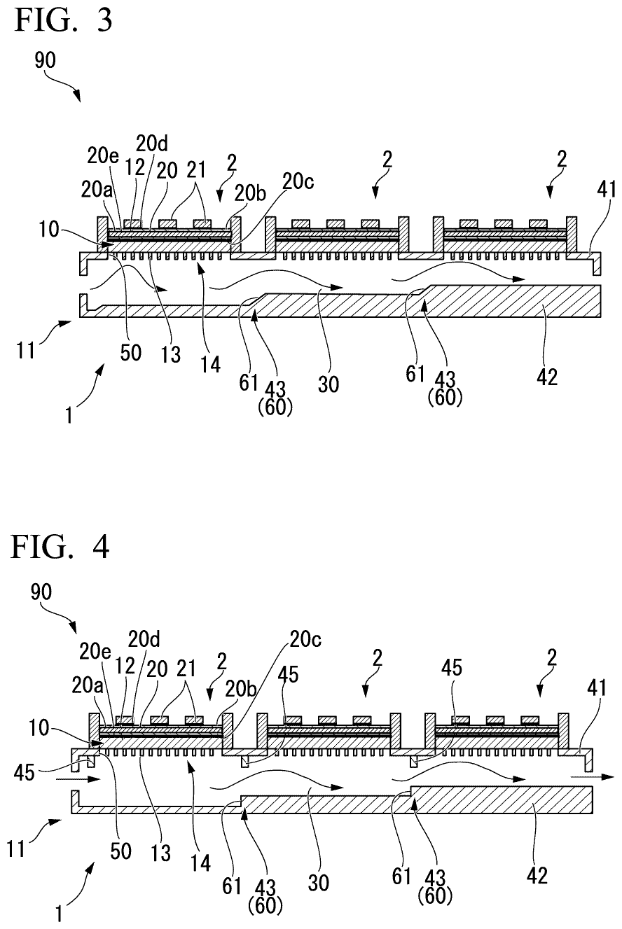

Furthermore, as shown in FIG. 3 as a second modification example, it is also possible to adopt a configuration in which the step difference surface 61 is inclined. More specifically, the step difference surface 61 is inclined from a side of the bottom surface portion 42 toward a side of the top surface portion 41 from the upstream side toward the downstream side. According to this configuration, in addition to an operational effect obtained by the above-described flow disturbance, the step difference surface 61 can reduce a pressure loss of the refrigerant when the refrigerant passes through the step difference surface 61. In this manner, the flow of the refrigerant is further smoothed, and the cooling effect on each power module 2 can be further improved.

### Second Embodiment

Subsequently, a second embodiment of the present disclosure will be described with reference to FIG. 4. The same reference numerals will be assigned to the same configurations as in the above-described first embodiment, and a detailed description thereof will be omitted. As shown in FIG. 4, in the present embodiment, each top surface-side protrusion portion 45 is provided as the flow disturbance portions 43 between the power modules 2 in the top surface portion 41. The top surface-side protrusion portion 45 protrudes in a direction from the top surface portion 41 toward a side of the bottom surface portion 42. In addition, the top surface-side protrusion portion 45 is provided at a position overlapping the step difference portion 60 of the bottom surface portion 42 in the first direction. The top surface-side protrusion portion 45 may be provided on a slightly upstream side or downstream side of the step difference portion 60.

### (Operational Effect)

According to the above-described configuration, since the top surface-side protrusion portion 45 is provided, the flow of the refrigerant climbing over the top surface-side protrusion portion 45 is disturbed. In this manner, the refrigerant is stirred, and the refrigerant flows to the downstream side in a state where the temperature gradient from a side of the top surface portion 41 to a side of the bottom surface portion 42 is eliminated. As a result, since a temperature increase on a side of the heat transfer surface 14 of the refrigerant flowing to the downstream side is suppressed, the cooling effect on the power module 2 on the downstream side can be further improved.

Hitherto, the second embodiment of the present disclosure has been described. Various changes or modifications can be made to the above-described configuration without departing from the concept of the present disclosure.

### Third Embodiment

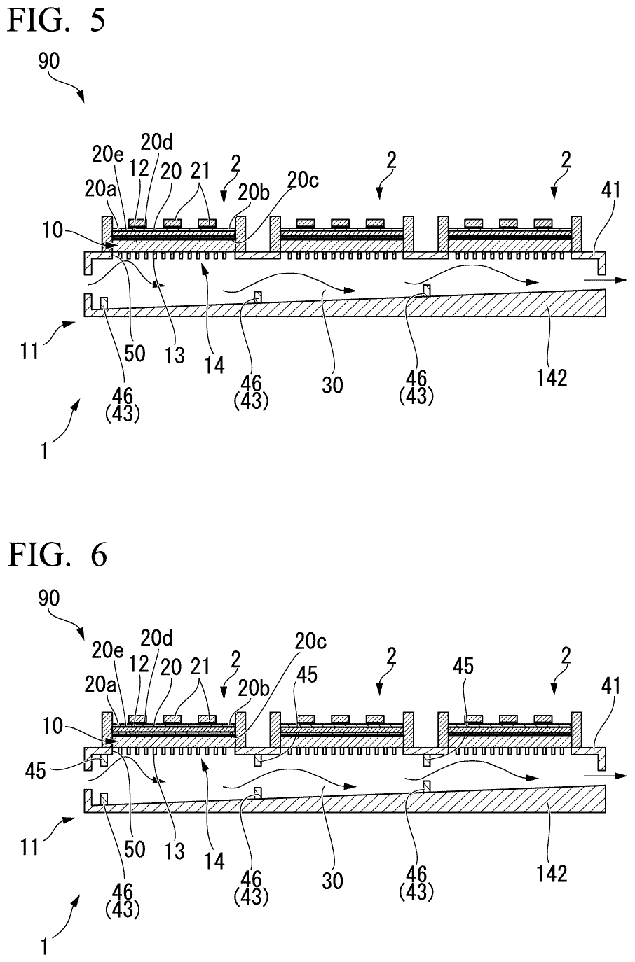

Next, a third embodiment of the present disclosure will be described with reference to FIG. 5. The same reference numerals will be assigned to the same configurations as in each of the above-described embodiments, and detailed description thereof will be omitted. As shown in FIG. 5, in the present embodiment, a surface of the bottom surface portion 142 is continuously inclined to be closer to the top surface portion 41 from the upstream side toward the downstream side. That is, the step difference portion 60 is not formed in the bottom surface portion 142 itself. In this manner, the flow path cross sectional area of the flow path 30 gradually decreases toward the downstream side. Furthermore, a bottom surface-side protrusion portion 46 serving as the flow disturbance portion 43 is provided on a surface of the bottom surface portion 142. The bottom surface-side protrusion portion 46 protrudes from the surface of the bottom surface portion 142 toward a side of the top surface portion 41. The bottom surface-side protrusion portion 46 is located between the pair of power modules 2 adjacent to each other in the first direction.

### (Operational Effect)

According to the above-described configuration, the bottom surface portion 142 is inclined toward a side of the top surface portion 41 as the bottom surface portion 142 faces the downstream side. In this manner, for example, compared to a case where a step difference or the like is provided in the bottom surface portion 142, the pressure loss generated in the refrigerant can be minimized. As a result, the flow of the refrigerant is smoothed, and a fresh refrigerant is always supplied to the downstream side. Therefore, a further improved cooling effect can be realized.

Furthermore, according to the above-described configuration, since the bottom surface-side protrusion portion 46 is provided, the flow of the refrigerant climbing over the bottom surface-side protrusion portion 46 is disturbed. In this manner, the refrigerant is stirred, and the refrigerant flows to the downstream side in a state where the temperature gradient from a side of the top surface portion 41 to a side of the bottom surface portion 142 is eliminated. As a result, since a temperature increase on a side of the heat transfer surface 14 of the refrigerant flowing to the downstream side is suppressed, the cooling effect on the power module 2 on the downstream side can be further improved.

Hitherto, the third embodiment of the present disclosure has been described. Various changes or modifications can be made to the above-described configuration without departing from the concept of the present disclosure.

For example, as shown in FIG. 6 as a modification example, the top surface-side protrusion portion 45 described in the second embodiment can be provided in the top surface portion 41. In this case, positions of the top surface-side protrusion portion 45 and the bottom surface-side protrusion portion 46 in the first direction may coincide with each other, or may be slightly shifted to the upstream side or the downstream side. According to this configuration, the same operational effects as those described above can also be achieved.

### Appendix

For example, the cooling device 1 described in each of the embodiments is understood as follows.
(1) According to a first aspect, there is provided the cooling device 1 for cooling the plurality of power modules 2 each including the substrate body 20 and the semiconductor element 21 disposed on the surface of the substrate body 20, and arrayed in the first direction. The cooling device 1 includes the cooling member 10 including the heat transfer surface 14 and provided in contact with the back surface of each of the substrate bodies 20, and the flow path forming member 11 including the top surface portion 41 in which the opening portion 50 surrounding the heat transfer surface 14 is formed and the bottom surface portion 42 facing the top surface portion 41 at an interval, and forming the flow path 30 through which the refrigerant flows in the first direction between the bottom surface portion 42 and the top surface portion 41. In the flow path 30, the flow path cross sectional area decreases from the upstream side toward the downstream side in the flow direction of the refrigerant. Each flow disturbance portion 43 configured to disturb the flow of the refrigerant is provided in the region between the power modules 2 in the flow path forming member 11.

According to the above-described configuration, the flow path cross sectional area of the flow path 30 decreases toward the downstream side. In this manner, a flow velocity of the refrigerant increases toward the downstream side. As a result, the heat transfer rate of the refrigerant increases as the refrigerant is closer to the power module 2 on the downstream side, and the cooling effect can be improved. Furthermore, the refrigerant flowing in the flow path 30 collides with the flow disturbance portion 43. Accordingly, the flow direction of the refrigerant is changed. In this manner, the refrigerant in which the temperature gradient is formed when supplied to cool the power module 2 on the upstream side is stirred. As a result, the refrigerant flows toward the power module 2 on the downstream side in a state where the temperature gradient is eliminated. In this manner, the cooling effect on the power module 2 on the downstream side can be further improved.
(2) As the cooling device 1 according to a second aspect, in the cooling device 1 according to (1), the flow disturbance portion 43 includes the step difference portion 60 including the step difference surface 61 facing the upstream side.

According to the above-described configuration, the flow path cross sectional area of the flow path 30 can be reduced toward the downstream side by forming the step difference portion 60. In this manner, the flow velocity of the refrigerant increases toward the downstream side. In addition, the refrigerant collides with the step difference surface 61 of the step difference portion 60. Accordingly, a flow disturbance including a vortex is generated on the downstream side of the step difference portion 60. As a result, the refrigerant is stirred, and the cooling effect on the power module 2 on the downstream side can be easily improved.

(3) As the cooling device 1 according to a third aspect, in the cooling device 1 according to (1) or (2), the flow disturbance portion 43 includes the top surface-side protrusion portion 45 protruding from the top surface portion 41 toward the bottom surface portion 42.

According to the above-described configuration, since the top surface-side protrusion portion 45 is provided, the flow of the refrigerant climbing over the top surface-side protrusion portion 45 is disturbed. In this manner, the refrigerant is stirred, and the refrigerant flows to the downstream side in a state where the temperature gradient is eliminated. As a result, the cooling effect on the power module 2 on the downstream side can be further improved.
(4) As the cooling device 1 according to a fourth aspect, in the cooling device 1 according to any one of (1) to (3), the flow disturbance portion 43 includes the bottom surface-side protrusion portion 46 protruding from the bottom surface portion 42 toward the top surface portion 41.

According to the above-described configuration, since the bottom surface-side protrusion portion 46 is provided, the flow of the refrigerant climbing over the bottom surface-side protrusion portion 46 is disturbed. In this manner, the refrigerant is stirred, and the refrigerant flows to the downstream side in a state where the temperature gradient is eliminated. As a result, the cooling effect on the power module 2 on the downstream side can be further improved.
(5) As the cooling device 1 according to a fifth aspect, in the cooling device 1 according to any one of (1) to (4), the bottom surface portion 142 is inclined toward a side of the top surface portion 41 from the upstream side toward the downstream side.

According to the above-described configuration, the bottom surface portion 142 is inclined toward a side of the top surface portion 41 as the bottom surface portion 142 faces the downstream side. In this manner, for example, compared to a case where a step difference or the like is provided in the bottom surface portion 142, a pressure loss generated in the refrigerant can be suppressed. As a result, the flow of the refrigerant is smoothed, and a further improved cooling effect can be realized.
(6) As the cooling device 1 according to a sixth aspect, the cooling device 1 according to any one of (1) to (5) further includes the upstream-side flow disturbance portion 44 provided on the further upstream side of the power module 2 located on the uppermost stream side in the bottom surface portion 42.

According to the above-described configuration, the upstream-side flow disturbance portion 44 is provided. When the air bubbles are generated due to the boiling of the refrigerant on the surface (heat transfer surface 14) of the cooling member 10 corresponding to the power module 2 on the uppermost stream side, the refrigerant passing through the upstream-side flow disturbance portion 44 flows toward the heat transfer surface 14. Accordingly, the air bubbles can be flowed away. As a result, the cooling effect can be continuously maintained by avoiding the occurrence of the dry-out on the heat transfer surface 14.
(7) As the cooling device 1 according to a seventh aspect, in the cooling device 1 according to any one of (1) to (6), the cooling member 10 includes the cooling member body 12 configured to come into contact with the substrate body 20, and the plurality of protrusions 13 protruding from the cooling member body 12 toward the bottom surface portion 42. The protrusion length of the protrusions 13 is equal to or smaller than the thickness of the top surface portion 41.

According to the above-described configuration, the protrusion length of the protrusion 13 of the cooling member 10 is equal to or smaller than the thickness of the top surface portion 41. In this manner, even when the air bubbles are generated due to the boiling of the refrigerant in the gap between the protrusions 13, the flow of the refrigerant easily reaches the inside of the gap. Therefore, the air bubbles can be easily flowed away by the flow of the refrigerant. As a result, it is possible to further reduce a possibility that the dry-out occurs.
(8) According to an eighth aspect, there is provided the cooling device 1 for cooling the plurality of power modules 2 each including the substrate body 20 and the semiconductor element 21 disposed on the surface of the substrate body 20, and arrayed in the first direction. The cooling device 1 includes the cooling member 10 including the heat transfer surface 14 and provided in contact with the back surface of each of the substrate bodies 20, and the flow path forming member 11 including the top surface portion 41 in which the opening portion 50 surrounding the heat transfer surface 14 is formed and the bottom surface portion 42 facing the top surface portion 41 at an interval, and forming the flow path 30 through which the refrigerant flows in the first direction between the bottom surface portion 42 and the top surface portion 41. In the flow path 30, the flow path cross sectional area decreases from the upstream side toward the downstream side in the flow direction of the refrigerant. The cooling member 10 includes the cooling member body 12 configured to come into contact with the substrate body 20, and the plurality of protrusions 13 protruding from the cooling member body 12 toward the bottom surface portion 42. The protrusion length of the protrusions 13 is equal to or smaller than the thickness of the top surface portion 41.

According to the above-described configuration, the flow path cross sectional area of the flow path 30 decreases toward the downstream side. In this manner, a flow velocity of the refrigerant increases toward the downstream side. As a result, the heat transfer rate of the refrigerant increases as the refrigerant is closer to the power module 2 on the downstream side, and the cooling effect can be improved. Furthermore, the protrusion length of the protrusion 13 of the cooling member 10 is equal to or smaller than the thickness of the top surface portion 41. In this manner, even when the air bubbles are generated due to the boiling of the refrigerant in the gap between the protrusions 13, the flow of the refrigerant easily reaches the inside of the gap. Therefore, the air bubbles can be easily flowed away by the flow of the refrigerant. As a result, it is possible to further reduce the possibility that the dry-out occurs.

### INDUSTRIAL APPLICABILITY

According to the present disclosure, it is possible to provide a cooling device which can stably cool a semiconductor element.

### REFERENCE SIGNS LIST

1 Cooling device
2 Power module
10 Cooling member
11 Flow path forming member
12 Cooling member body
13 Protrusion
14 Heat transfer surface
20 Substrate body
20a Insulator
20b Pattern
20c Pattern
21
20d Bonding member
20e Bonding member
21 Semiconductor element
30 Flow path
41 Top surface portion
42 Bottom surface portion
43 Flow disturbance portion
44 Upstream-side flow disturbance portion
45 Top surface-side protrusion portion
46 Bottom surface-side protrusion portion
50 Opening portion
60 Step difference portion
61 Step difference surface
90 Circuit system
142 Bottom surface portion

1. A cooling device for cooling a plurality of power modules each including a substrate body and a semiconductor element disposed on a surface of the substrate body, and arrayed in a first direction, the cooling device comprising:
a cooling member including a heat transfer surface and provided in contact with a back surface of each of the substrate bodies; and
a flow path forming member including a top surface portion in which an opening portion surrounding the heat transfer surface is formed and a bottom surface portion facing the top surface portion at an interval, and forming a flow path through which a refrigerant flows in the first direction between the bottom surface portion and the top surface portion, wherein
in the flow path, a flow path cross sectional area decreases from an upstream side toward a downstream side in a flow direction of the refrigerant, and
each flow disturbance portion configured to disturb a flow of the refrigerant is provided in a region between the power modules in the flow path forming member.

2. The cooling device according to claim 1, wherein the flow disturbance portion includes a step difference portion including a step difference surface facing the upstream side.

3. The cooling device according to claim 1, wherein the flow disturbance portion includes a top surface-side protrusion portion protruding from the top surface portion toward the bottom surface portion.

4. The cooling device according to claim 1, wherein the flow disturbance portion includes a bottom surface-side protrusion portion protruding from the bottom surface portion toward the top surface portion.

5. The cooling device according to claim 1, wherein the bottom surface portion is inclined toward a side of the top surface portion from the upstream side toward the downstream side.

6. The cooling device according to claim 1, further comprising:
an upstream-side flow disturbance portion provided on a further upstream side of the power module located on an uppermost stream side in the bottom surface portion.

7. The cooling device according to claim 1, wherein
the cooling member includes
a cooling member body configured to come into contact with the substrate body, and
a plurality of protrusions protruding from the cooling member body toward the bottom surface portion, and
a protrusion length of the protrusion is equal to or smaller than a thickness of the top surface portion.

8. A cooling device for cooling a plurality of power modules each including a substrate body and a semiconductor element disposed on a surface of the substrate body, and arrayed in a first direction, the cooling device comprising:
a cooling member including a heat transfer surface and provided in contact with a back surface of each of the substrate bodies; and
a flow path forming member including a top surface portion in which an opening portion surrounding the heat transfer surface is formed and a bottom surface portion facing the top surface portion at an interval, and forming a flow path through which a refrigerant flows in the first direction between the bottom surface portion and the top surface portion, wherein
in the flow path, a flow path cross sectional area decreases from an upstream side toward a downstream side in a flow direction of the refrigerant,
the cooling member includes
a cooling member body configured to come into contact with the substrate body, and
a plurality of protrusions protruding from the cooling member body toward the bottom surface portion, and
a protrusion length of the protrusion is equal to or smaller than a thickness of the top surface portion.

9. The cooling device according to claim 2, wherein the flow disturbance portion includes a top surface-side protrusion portion protruding from the top surface portion toward the bottom surface portion.
